(19) United States
(12) Patent Application Publication
(10) Pub. No.: US 2023/0020152 A1
(43) Pub. Date: Jan. 19, 2023

(54) PLATE VAPOR CHAMBER ARRAY ASSEMBLY

(71) Applicant: Yue Zhang, Shanghai (CN)

(72) Inventor: Yue Zhang, Shanghai (CN)

(21) Appl. No.: 17/948,116

(22) Filed: Sep. 19, 2022

Related U.S. Application Data
(63) Continuation-in-part of application No. 15/980,557, filed on May 15, 2018, now Pat. No. 11,448,469.
Application No. 15/980,557 is a continuation-in-part of application No. 14/335,649, filed on Jul. 18, 2014, now abandoned.

(51) Int. Cl. F28D 15/04

(52) U.S. Cl. CPC F28D 15/04

(57) ABSTRACT

A plate vapor chamber array assembly with a plurality of plate vapor chambers joined in an array and each chamber having an evaporation area and an evacuated sealed chamber. The plate vapor chambers may be in direct contact with adjacent plate vapor chambers. A vapor chamber clamp surrounding the array has an inner surface engaging an outer edge of at least two of the plate vapor chambers of the array to press a surface of the plate vapor chamber array directly against the heat source.

### CROSS REFERENCE TO RELATED APPLICATIONS

This application is a continuation-in-part application of U.S. patent application Ser. No. 15/980,557 entitled “HEAT-WING” to Yue Zhang that was filed on May 15, 2018, which is a continuation-in-part application of U.S. patent application Ser. No. 14/335,649 entitled “HEAT-WING” to Yue Zhang, that was filed on Jul. 18, 2014, the disclosures of each of which are hereby incorporated herein by this reference.

### TECHNICAL FIELD

The present disclosure relates generally to phase-change heat radiators, and particularly to a plate vapor chamber and use thereof.

### BACKGROUND

Compared to high thermal conductivity solid metal blocks, phase-change heat radiators have higher equivalent thermal conductivities and better heat dissipation performance. They are widely used because of a variety of advantages, such as a high thermal conductivity and good temperature uniformity. These advantages are realized by liquid working media sealed in the heat radiators, on the phase transition of which the heat radiators rely for heat transfer. Currently, heat pipes and vapor chambers are two types of commonly used phase-change heat radiators.

Referring to FIG. 1, a typical heat pipe is composed of a hollow cylindrical chamber 11, a capillary structure 12 and a phase transition working medium 13 hermetically sealed in the chamber. Fabrication of the heat pipe generally includes: vacuuming the chamber and partially filling the chamber with the working medium 13; impregnating the capillary structure 12, which is closely attached to an inner surface of the chamber 11, with the working medium 13; and sealing the chamber. One end of the heat pipe serves as an evaporation area 14 which is brought in contact with a heat source for extracting heat from the source, while the other end acts as a condensation area 15 for dissipating heat, directly, or with the aid of auxiliary equipment such as fans for a higher efficiency. The rest section of the heat pipe between the evaporator and condensation areas 14 and 15 is referred to as an adiabatic section. When the evaporation area 14 is being heated, the working liquid medium 13 in the capillary structure 12 vaporizes into a vapor working medium 16. The vapor working medium subsequently flows through ducts 17 under the action of a differential pressure and enters the condensation area 15, where it condenses back to the liquid working medium 13, releasing the heat. Thereafter, the restored liquid working medium 13 flows along the capillary structure 12 under a capillary pressure and returns to the evaporation area 14. With the repetition of this cycle, heat 18 is continuously transferred from the evaporation area 14 to the condensation area 15 and thereby realizes heat dissipation. However, as the heat pipe has a relatively small diameter, the vapor transport occurs therein in a nearly one-dimensional, linear manner. Moreover, limited by the narrow ducts for vapor transport and a minimal flow-back passage width of the liquid working medium, the heat pipe tends to reach its heat transfer limit before operating at the optimal performance level.

As an improved type of heat pipe, Chinese patent publication No. CN201364059Y discloses a vapor chamber, or called a flat plate heat pipe. As shown in FIG. 2, each of the vapor chambers 42 and 42′ uses its two plates to serve as working plates. In the vapor chamber, vapor is transported in a nearly two-dimensional, planar manner. Compared with heat pipe, the vapor chamber provides a larger vapor passage area and a larger liquid working medium flow-back passage width, thus ensuring better temperature uniformity than that of a heat pipe. However, during use of this kind of vapor chambers 42 and 42′, heat is transferred successively through a heat conduction piece 41 and clamps 412 for fixing the vapor chambers which are arranged in a direction perpendicular to the plane of the heat source and finally reaches the plates of the vapor chambers 42 and 42′. In such a configuration, the distance from the heat source to the vapor chambers is too long, with an average distance equal to a thickness of the heat conduction piece 41 plus half of a height of the clamp, while a total heat conduction width in the clamps 412 is too short, which is only a sum of the widths of the two clamps 412, thereby results in a relatively high thermal resistance.

### SUMMARY

Aspects of this document relate to a plate vapor chamber array assembly comprising a plurality of plate-shaped chambers joined in an array with each of the plate-shaped chambers in direct contact with at least one adjacent plate-shaped chamber of the array, each plate-shaped chamber formed by a first plate spaced from a second plate forming a condensation area having a length and a height, the first plate and the second plate connected together by a frame, the frame forming an evaporation area on a first end of the chamber between a first end of the first plate and a first end of the second plate, the evaporation area having a thickness defined as a distance between the first plate and the second plate, and an evaporation length defined as a length of the evaporation area, the evaporation length of the evaporation area within the chamber being greater than the thickness of the evaporation area, the frame sealing the first plate to the second plate thereby forming a sealed chamber having an enclosed and hollow space defined by the chamber on an inside of the first plate, the second plate, and the frame, a capillary structure layer within each of the plurality of plate-shaped chambers, each chamber and adjacent inner surfaces of at least a part of the first plate and the second plate, the capillary structure layer for each of the plurality of plate-shaped chambers further attached to an inner surface of at least a part of the frame, a phase transition working medium sealed within the sealed chamber of each of the plurality of plate-shaped chambers, each of the sealed chambers being evacuated, and a vapor chamber clamp surrounding the array and comprising at least one vapor chamber opening within the vapor chamber clamp and having an inner surface of the vapor chamber clamp opening configured to engage an outer edge of at least two of the plate vapor chambers of the array, wherein the vapor chamber clamp is configured to press a surface of the plate vapor chamber array directly against the heat source, wherein the evaporation area is configured to be coupled with the evaporation length and its thickness in direct, planar, physical contact with a heat source, and wherein the condensation area is configured to not be in direct physical contact with the heat source, and is configured to extend away from the heat source.

Particular embodiments may comprise one or more of the following features. The evaporation length of the evaporation area within the chamber is greater than the thickness of the evaporation area by at least five times. The evaporation length of the evaporation area within the chamber is greater than the thickness of the evaporation area by at least two times. The at least one vapor chamber opening in the clamp comprises a plurality of vapor chamber openings, each sized to receive at least one plate vapor chamber therethrough. The inner surface of the at least one vapor chamber clamp opening is angled non-perpendicular to an upper and lower surface of the vapor chamber clamp. The inner surface of each of the at least one vapor chamber clamp openings is shaped to mate with the plurality of plate shaped chambers. At least one heat dissipating fin extending between at least two chambers of the plurality of plate-shaped chambers. The at least one heat dissipating fin is in a zig-zag shape extending back and forth between the at least two chambers of the plurality of plate-shaped chambers.

Aspects of this document relate to a plate vapor chamber array assembly comprising a plurality of plate vapor chambers joined in an array with each of the vapor plate chambers in close arrangement with at least one adjacent plate vapor chamber of the array, each plate vapor chamber formed by a first plate spaced from a second plate forming a condensation area having a length and a height, the first plate and the second plate connected together by a frame, the frame forming an evaporation area on a first end of the chamber between a first end of the first plate and a first end of the second plate, the evaporation area having a thickness defined as a distance between the first plate and the second plate, and an evaporation length defined as a length of the evaporation area, the evaporation length of the evaporation area within the chamber being greater than the thickness of the evaporation area, the frame sealing the first plate to the second plate thereby forming a sealed chamber having an enclosed and hollow space defined by the chamber on an inside of the first plate, the second plate, and the frame, the sealed chamber being evacuated, and a vapor chamber clamp surrounding the array and having an inner surface of a vapor chamber clamp opening configured to engage an outer edge of at least two of the plate vapor chambers of the array and to press a surface of the plate vapor chamber array directly against the heat source, wherein the evaporation area is configured to be coupled with the evaporation length and its thickness in direct, planar, physical contact with a heat source, and wherein the condensation area is configured to not be in direct physical contact with the heat source, and is configured to extend away from the heat source.

Particular embodiments may comprise one or more of the following features. The evaporation length of the evaporation area within the chamber is greater than the thickness of the evaporation area by at least five times. The at least one vapor chamber opening in the clamp comprises a plurality of vapor chamber openings, each sized to receive at least one plate vapor chamber therethrough. The inner surface of the at least one vapor chamber clamp opening is angled non-perpendicular to an upper and lower surface of the vapor chamber clamp. The inner surface of each of the at least one vapor chamber clamp openings is shaped to mate with the plurality of plate shaped chambers. At least one heat dissipating fin extending between at least two chambers of the plurality of plate-shaped chambers.

Aspects of this document relate to a plate vapor chamber array assembly comprising a plurality of plate vapor chambers joined in an array, each plate vapor chamber comprising a condensation area having a length and a height, the first plate and the second plate connected together by a frame, the frame forming an evaporation area on a first end of the chamber and sealing the first plate to the second plate thereby forming a sealed chamber having an enclosed and hollow space defined by the chamber on an inside of the first plate, the second plate, and the frame, the sealed chamber being evacuated, and a vapor chamber clamp surrounding the array and having an inner surface of a vapor chamber clamp opening configured to engage an outer edge of at least two of the plate vapor chambers of the array and to press a surface of the plate vapor chamber array directly against the heat source.

Particular embodiments may comprise one or more of the following features. The at least one vapor chamber opening in the clamp comprises a plurality of vapor chamber openings, each sized to receive at least one plate vapor chamber therethrough. The inner surface of the at least one vapor chamber clamp opening is angled non-perpendicular to an upper and lower surface of the vapor chamber clamp. At least two of the vapor plate chambers in direct contact with at least one adjacent plate vapor chamber of the array. At least one heat dissipating fin extending between at least two chambers of the plurality of plate-shaped chambers. The at least one heat dissipating fin is in a zig-zag shape extending back and forth between the at least two chambers of the plurality of plate-shaped chambers.

A phase-change heat radiator is disclosed with a large vapor passage area, large working medium flow-back passage width, short evaporator center-to-edge distance, large condenser heat dissipation area and high heat transfer limit.

An aspect of the present disclosure provides a plate vapor chamber, which includes: a sealed hollow chamber, including two plates and a frame connecting the two plates; a capillary structure layer closely attached to an inner surface of the chamber; and a phase transition working medium sealed in the chamber. Wherein, a portion of the frame or a portion of a periphery of one of the two plates is in direct contact with a heat source and thereby serves as an evaporation area of the plate vapor chamber, and the rest portion of the chamber that is not in contact with the heat source serves as a condensation area of the plate vapor chamber. Wherein, each of a length and a width of the chamber is much greater than a thickness of the chamber.

In one or more particular embodiments, materials that the chamber can be fabricated from include copper, aluminum, stainless steel metal and alloys thereof, high thermal conductivity ceramics, and other high thermal conductivity materials. In one or more particular embodiments, the capillary structure layer may be a single- or multi-layer structure made of sintered powder(s), wire lattices, grooves etched into the chamber, fibers, coated or grown carbon nanowalls, carbon nanotubes or carbon nanocapsules, other coated or grown nan- or micro-order thin organic or inorganic layer(s), or any combination of the above, or any other suitable structure providing capillary attraction. In one or more particular embodiments, materials that may be used as the phase transition working medium include water and other liquids, low melting point metals, carbon nanocapsules, other nanoparticles, mixtures of the above materials, and other materials having gas-liquid phase transition at a temperature within the operating temperature range of the plate vapor chamber.

In one or more particular embodiments, the two plates are parallel or substantially parallel to each other. In one or more particular embodiments, each of the plates may assume a rectangular shape or any other shape, and may be flat or curved. In one or more particular embodiments, the plate vapor chamber has a cross-sectional area of a section near to the evaporation area that is larger than a cross-sectional area of an upper section of the plate vapor chamber. Alternatively, the cross-sectional area of the section near to the evaporation area may also be smaller than or equal to the cross-sectional area of the top section. In one or more embodiments, the plate vapor chamber may be evacuated to a certain degree of vacuum, and may accordingly further include a support or connection structure disposed between the two plates according to the mechanical strength of the chamber and positive and negative pressures to be applied thereto. In one or more embodiments, the support or connection structure may assume the shape of a dot, a line or a sheet.

In one or more embodiments, the plate vapor chamber may further include a fin. In one or more embodiments, the plate vapor chamber and/or the fin may be coated with a black-body radiator material. In one or more embodiments, the plate vapor chamber may further include a hose for vacuuming and liquid filling. In one or more embodiments, an array of the plate vapor chambers may be disposed on a heat source.

An aspect of the present disclosure provides an apparatus which includes a heat-generating component and at least one plate vapor chamber each including: a sealed hollow chamber including two plates and a frame connecting the two plates; a capillary structure layer closely attached to an inner surface of the chamber; and a phase transition working medium sealed in the chamber, wherein each plate vapor chamber has a portion of the frame or a portion of a periphery of one of the two plates thereof in direct contact with the heat-generating component and thereby serving as an evaporation area of the plate vapor chamber, and the rest portion of the chamber that is not in contact with the heat-generating component serves as a condensation area of the plate vapor chamber, wherein each of a length and a width of the chamber of each plate vapor chamber is much greater than a thickness thereof.

Compared with a conventional plate vapor chamber, plate vapor chambers according to the present disclosure may have one or more of the following advantages: as the plate vapor chamber of the present disclosure is a hermetically sealed plate-shaped hollow chamber having a length and width both much greater than its thickness, by bringing a portion of a periphery of one of the two plates or a portion of the frame, which has a limited area relative to the whole chamber area, into contact with the surface of the heat source so as to make it serve as an evaporation area, vapor is transported in a nearly two-dimensional, planar manner in the plate vapor chamber, which results in a large passage area for vapor transport and ensures a high temperature uniformity; since the gap between the two plates is very small, a very short evaporation area center-to-edge distance can be achieved, thereby addressing the issue of early dry-out of the evaporation area central area; by using the two relatively large plates as a condensation area, the plate vapor chamber ensures an extremely large condensation area which facilitates the heat dissipation, and provides a large working medium flow-back passage width which is about two times the width of the plate vapor chamber and allows a large flux of the working medium. The plate vapor chamber of the present disclosure has a greatly improved heat transfer limit and is hence capable of achieving a higher heat flux density over the conventional.

The foregoing and other aspects, features, applications, and advantages will be apparent to those of ordinary skill in the art from the specification, drawings, and the claims. Unless specifically noted, it is intended that the words and phrases in the specification and the claims be given their plain, ordinary, and accustomed meaning to those of ordinary skill in the applicable arts. The inventors are fully aware that he can be his own lexicographer if desired. The inventors expressly elect, as their own lexicographers, to use only the plain and ordinary meaning of terms in the specification and claims unless they clearly state otherwise and then further, expressly set forth the “special” definition of that term and explain how it differs from the plain and ordinary meaning. Absent such clear statements of intent to apply a “special” definition, it is the inventors' intent and desire that the simple, plain and ordinary meaning to the terms be applied to the interpretation of the specification and claims.

The inventors are also aware of the normal precepts of English grammar. Thus, if a noun, term, or phrase is intended to be further characterized, specified, or narrowed in some way, then such noun, term, or phrase will expressly include additional adjectives, descriptive terms, or other modifiers in accordance with the normal precepts of English grammar. Absent the use of such adjectives, descriptive terms, or modifiers, it is the intent that such nouns, terms, or phrases be given their plain, and ordinary English meaning to those skilled in the applicable arts as set forth above.

Further, the inventors are fully informed of the standards and application of the special provisions of 35 U.S.C. § 112(f). Thus, the use of the words “function,” “means” or “step” in the Detailed Description or Description of the Drawings or claims is not intended to somehow indicate a desire to invoke the special provisions of 35 U.S.C. § 112(f), to define the invention. To the contrary, if the provisions of 35 U.S.C. § 112(f) are sought to be invoked to define the inventions, the claims will specifically and expressly state the exact phrases “means for” or “step for”, and will also recite the word “function” (i.e., will state “means for performing the function of [insert function]”), without also reciting in such phrases any structure, material or act in support of the function. Thus, even when the claims recite a “means for performing the function of . . . ” or “step for performing the function of . . . ,” if the claims also recite any structure, material or acts in support of that means or step, or that perform the recited function, then it is the clear intention of the inventors not to invoke the provisions of 35 U.S.C. § 112(f). Moreover, even if the provisions of 35 U.S.C. § 112(f) are invoked to define the claimed aspects, it is intended that these aspects not be limited only to the specific structure, material or acts that are described in the preferred embodiments, but in addition, include any and all structures, materials or acts that perform the claimed function as described in alternative embodiments or forms of the disclosure, or that are well known present or later-developed, equivalent structures, material or acts for performing the claimed function.

The foregoing and other aspects, features, and advantages will be apparent to those of ordinary skill in the art from the specification, drawings, and the claims.

### BRIEF DESCRIPTION OF DRAWINGS

Implementations will hereinafter be described in conjunction with the appended drawings, where like designations denote like elements, and:

FIG. 1 shows a schematic cross-section view of a conventional heat pipe.

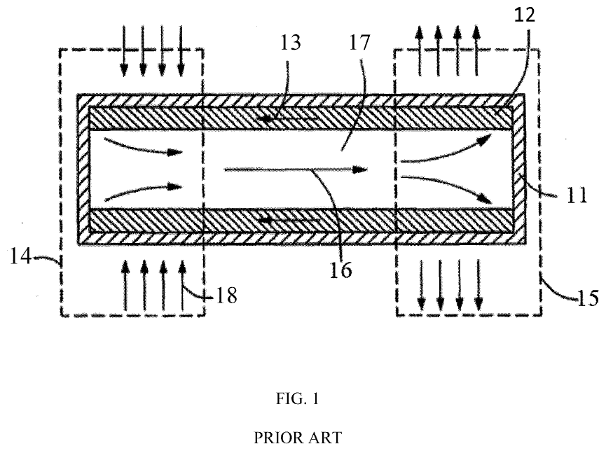

FIG. 2 shows a schematic cross-section view of a conventional vapor chamber.

FIG. 3 shows a three-dimensional view of a plate vapor chamber in accordance with a first embodiment of the present disclosure.

FIG. 4 shows a schematic cross-sectional view taken along the line A-A of FIG. 3.

FIG. 5 shows a schematic cross-sectional view of a plate vapor chamber in accordance with a second embodiment of the present disclosure.

FIG. 6 shows a schematic cross-sectional view of a plate vapor chamber in accordance with a third embodiment of the present disclosure.

FIG. 7 shows a schematic cross-sectional view of a plate vapor chamber in accordance with a fourth embodiment of the present disclosure.

FIG. 8 shows a schematic cross-sectional view of a plate vapor chamber in accordance with a fifth embodiment of the present disclosure.

FIG. 9 shows a schematic cross-sectional view of a plate vapor chamber in accordance with a sixth embodiment of the present disclosure.

FIG. 10 shows a three-dimensional view of a plate vapor chamber array in accordance with a seventh embodiment of the present disclosure.

FIG. 11 shows a schematic cross-sectional view of a plate vapor chamber array in accordance with an eighth embodiment of the present disclosure.

FIG. 12 is an exploded three-dimensional view of FIG. 11.

FIG. 13 shows a three-dimensional view of a plate vapor chamber array in accordance with a ninth embodiment of the present disclosure.

FIG. 14 shows a three-dimensional view of a plate vapor chamber assembled array in accordance with a tenth embodiment of the present disclosure.

FIG. 15 is an exploded perspective view of FIG. 14.

FIG. 16 shows a three-dimensional view of a plate vapor chamber assembled array in accordance with a eleventh embodiment of the present disclosure.

FIG. 17 shows working-principle view.

FIG. 18 shows the structural view of inner supporting of the plate vapor chamber.

FIG. 19 shows a three-dimensional view of a plate vapor chamber array similar to that illustrated in FIGS. 11-12, but further comprising a plate vapor chamber clamp.

FIG. 20 shows a cross-sectional view of the clamp of the plate vapor chamber and clamp assembly of FIG. 19.

FIG. 21 shows an exploded three-dimensional view of a plate vapor chamber array with a clamp but further including a heat dissipation fin.

FIG. 22 shows an assembled three-dimensional view of the plate vapor chamber array assembly of FIG. 21.

FIG. 23 shows a cross-sectional view of the assembled plate vapor chamber array assembly of FIG. 22 taken along section line B-B.

FIG. 24 shows a cross-sectional view of an assembled plate vapor chamber 2 array assembly similar to that in FIG. 20 or FIG. 22.

FIG. 25 shows an exploded three-dimensional view of a plate vapor chamber array assembly with a second clamp embodiment.

FIG. 26 shows a cross-sectional view of a clamp according to the second embodiment with plate vapor chamber sections taken along section lines C-C of FIG. 25.

FIG. 27 shows a cross-sectional view of the clamp of FIG. 26 with a portion of a cross-sectional view of a plate vapor chamber array assembled with the clamp.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of implementations.

### DETAILED DESCRIPTION

This disclosure, its aspects and implementations, are not limited to the specific material types, components, methods, or other examples disclosed herein. Many additional material types, components, methods, and procedures known in the art are contemplated for use with particular implementations from this disclosure. Accordingly, for example, although particular implementations are disclosed, such implementations and implementing components may comprise any components, models, types, materials, versions, quantities, and/or the like as is known in the art for such systems and implementing components, consistent with the intended operation.

The word “exemplary,” “example,” or various forms thereof are used herein to mean serving as an example, instance, or illustration. Any aspect or design described herein as “exemplary” or as an “example” is not necessarily to be construed as preferred or advantageous over other aspects or designs. Furthermore, examples are provided solely for purposes of clarity and understanding and are not meant to limit or restrict the disclosed subject matter or relevant portions of this disclosure in any manner. It is to be appreciated that a myriad of additional or alternate examples of varying scope could have been presented, but have been omitted for purposes of brevity.

In the following description, reference is made to the accompanying drawings which form a part hereof, and which show by way of illustration possible implementations. It is to be understood that other implementations may be utilized, and structural, as well as procedural, changes may be made without departing from the scope of this document. As a matter of convenience, various components will be described using exemplary materials, sizes, shapes, dimensions, and the like. However, this document is not limited to the stated examples and other configurations are possible and within the teachings of the present disclosure. As will become apparent, changes may be made in the function and/or arrangement of any of the elements described in the disclosed exemplary implementations without departing from the spirit and scope of this disclosure.

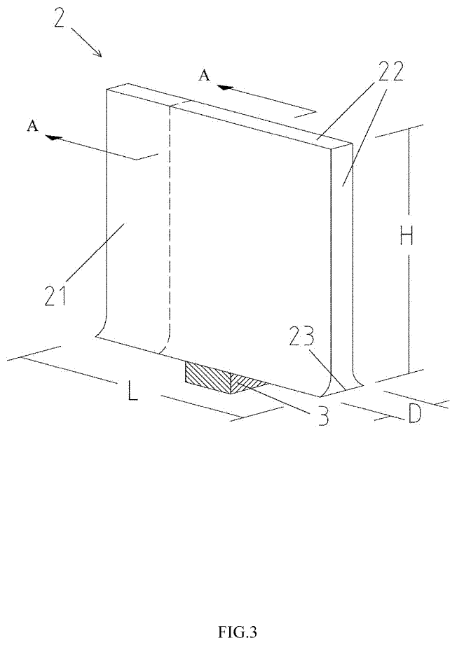

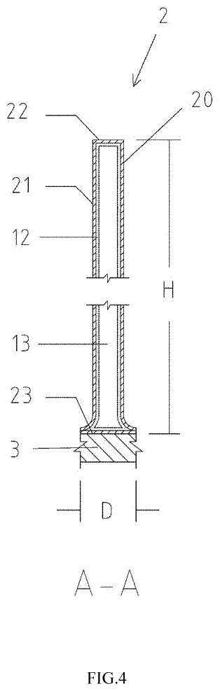

A first embodiment of the present disclosure is shown in FIGS. 3 and 4. As illustrated, the plate vapor chamber of the present disclosure includes a chamber 2 which is essentially a hollow plate-shaped structure including the first plate 20, the second plate 21 and a second portion 22 of the frame and a first portion 23 of the frame connecting the two plates (20 and 21). The plate vapor chamber further includes a capillary structure layer 12 which is closely attached to an inner surface of the chamber 2, and a phase transition working medium 13 hermetically sealed in the chamber 2. The first outside surface portion of the frame 23 comes in contact with a heat source 3, and thus functions as an evaporation area, while the rest portion of the chamber 2 acts as a condensation area. Alternatively, it is also possible to use a portion of a periphery of one of the first plate 20 and the second plate 21 to serve as the evaporation area.

Each of a length and a height of the plate vapor chamber is much greater than a thickness of the plate vapor chamber. As a result, the plate vapor chamber possesses a large passage area for vapor transport, ensuring high temperature uniformity. Additionally, since the gap between the two plates 21 (i.e., the thickness of the plate vapor chamber) is very small, bringing a portion of a periphery of one plate 21 or the first outside surface portion of the frame 23, which has a limited area relative to the whole area of thin plate-shaped chamber 2, into direct contact with the heat source 3 so as to make it serve an evaporation area realizes a very short evaporator center-to-edge distance, thereby addressing the issue of early dry-out of the evaporation area central area. In other embodiments, other thermally conductive materials may be inserted between the heat source and the outside surface of the frame 23.

Moreover, by using the two relatively large plates of the chamber to serve as a condensation area, the plate vapor chamber ensures a large condensation area, which facilitates heat dissipation and vapor condensation. In addition, this feature allows a larger passage width for the flow-back of the working medium 13 and hence increases the flux of the medium. For these reasons and others, the plate vapor chamber has a greatly improved heat transfer limit and is hence capable of achieving a higher heat flux density.

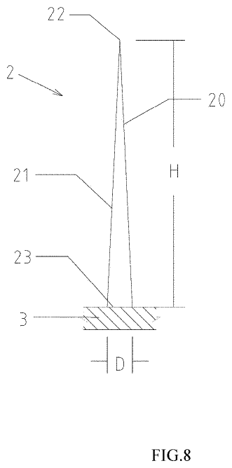

Herein, the height of the plate vapor chamber, i.e., the height of the hollow chamber 2, is defined as a dimension projecting away from a plane of the heat source, i.e., the height is a distance from a side of the two plates contacting the heat source 3 to the opposite side of the two plates which is farthest from the heat source 3. Therefore, for flat plates 20 and 21 (e.g., that shown in FIG. 8), the distance is the length of a straight line, and for curved plates 20 and 21 (e.g., those shown in FIGS. 4 to 7, and 11), the distance is the length of a curve. length of the plate vapor chamber, i.e., the length of the hollow chamber 2, is defined as a dimension extending in parallel to the plane of the heat source.

The length, height and thickness of each of the examples of plate vapor chambers disclosed herein may vary with specific needs of different applications, but a common requirement for these dimensions in particular embodiments is that both the length and height should be much greater than the thickness. In one particular embodiment, both the length and the height should be at least one order of magnitude greater. The present disclosure is, however, not limited in this regard, because those skilled in the art may design suitable length, height and thickness for the plate vapor chamber without departing from the spirit of the present disclosure, based on their knowledge.

In some situations, such a large improvement in heat dissipation is not needed and fewer plate vapor chambers are needed on the heat source to increase the heat dissipation several fold. In these situations, a smaller aspect ratio for the evaporation zone, less than an order of magnitude, is sufficient. Thus, in other particular embodiments, both the length and height are at least five times greater than the thickness. In other particular embodiments, the length and height are at least three times greater than the thickness. And in still other particular embodiments, both the length and height are at least two times greater than the thickness.

Materials that the chamber 2 can be fabricated from include copper, aluminum, stainless steel and alloy thereof, high thermal conductivity ceramics, and other high thermal conductivity materials, each of which can ensure a good heat transfer performance of the plate vapor chamber. The capillary structure layer 12 may be a single—or multi-layer structure made of sintered powder(s), wire lattices, grooves etched into the chamber, fibers, coated or grown carbon nanowalls, carbon nanotubes or carbon nanocapsules, other coated or grown nano- or micro-order thin organic or inorganic layer(s), or any combination of the above, or any other suitable structure providing capillary attraction.

Materials that may be used as the working medium 13 sealed in the plate vapor chamber include water and other liquids, low melting point metals, carbon nanocapsules, other nanoparticles, mixtures of the above materials, and other materials having gas-liquid phase change at a temperature within the operating temperature range of the plate vapor chamber. The plate vapor chamber may be evacuated to a certain degree of vacuum, and may accordingly further include a support or connection structure (not shown) disposed between the first plate 20 and the second plate 21. The support or connection structure may be designed according to the mechanical strength of the chamber 2 and positive and negative pressures to be applied thereto. The support or connection structure may assume the shape of a dot, a line, a sheet or any other shape. Further, in some alternative embodiments in which the chamber 2 has a sufficient strength to sustain the required load, the plate vapor chamber may not include the support or connection structure.

In the first embodiment, the two plates 20 and 21 are in parallel to each other except in their bottom sections, and a bottom section of the chamber 2 that is in close contact with the heat source 3 is thicker than an upper section of the plate vapor chamber. In some alternative embodiments of the disclosure, the plates 20 and 21 are parallel to each other, or the chamber 2 may have different thicknesses in its top and bottom sections.

The plate vapor chamber may further include auxiliary features arranged on the plates, such as, for example, fin(s) (not shown), tube(s) for vacuuming and liquid filling (not shown) and the like. The fin(s) is capable of facilitating the dissipation of heat from the interior of the plate vapor chamber. In addition, for a better heat transfer performance, the plate vapor chamber and/or the Min(s) can be coated with a black-body radiator material in order to further promote heat dissipation from the interior of the plate vapor chamber and fin(s). The tube(s) can be used in creating a desired vacuum condition for the working medium in the plate vapor chamber. It is to be noted that the plate vapor chamber may not include the fin(s) and tube(s) in some alternative embodiments.

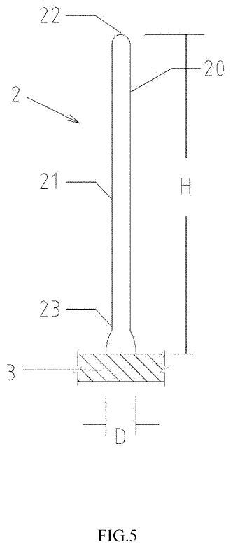

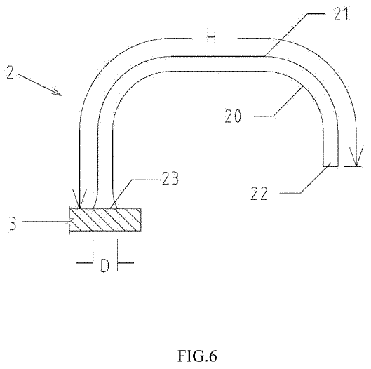

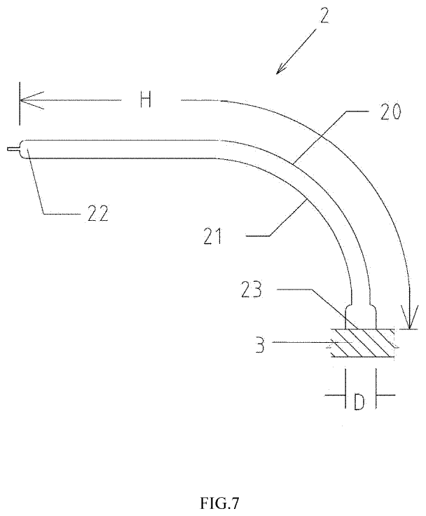

Plate vapor chambers constructed in accordance with second to sixth embodiments of the disclosure are respectively shown in FIGS. 5 to 9. As demonstrated in FIGS. 5 to 7, the plate vapor chamber of the present disclosure may have different cross-sectional shapes of a bottom section thereof, such as, a convex arc shape of a bottom section of the plates 20 and 21 proximal to the evaporation area shown in FIG. 5, a concave arc shape shown in FIG. 6, and a substantially rectangular shape shown in FIG. 7. In addition, the first outside surface portion of the frame 23 of the chamber may be slightly thicker than the second outside surface portion of the frame 22 of the plate vapor chamber. Alternatively, it can be appreciated that the first outside surface portion of the frame 23 of the plate vapor chamber may also have a thickness the same or smaller than that of the second outside surface portion of the frame 22 of the plate vapor chamber.

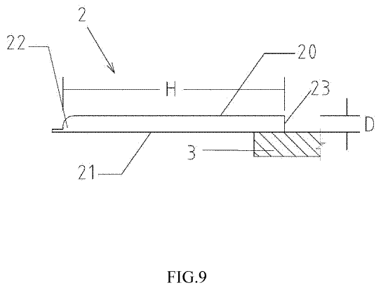

As demonstrated in FIGS. 4 to 9, the frame of the plate vapor chamber may either include a first portion of the frame 23 and a second portion of the frame 22 (as shown in FIGS. 4 to 7, and 9), or only includes the first outside surface portion of the frame 23, the second outside surface portion of the frame does not exist or partially does not exist (as shown in FIG. 8). In the latter case, the hollow chamber may be closed at the top by directly connecting top portions of the two plates 20 and 21. Further, as shown in FIGS. 4 to 7, and 9, the second outside surface portion of the frame 22 may be closed by different techniques and thus have different shapes, such as, for example, an arc shape shown in FIG. 5, a linear shape shown in FIG. 6, and a shape with a protrusion which may be formed at different positions as shown in FIGS. 7 and 9.

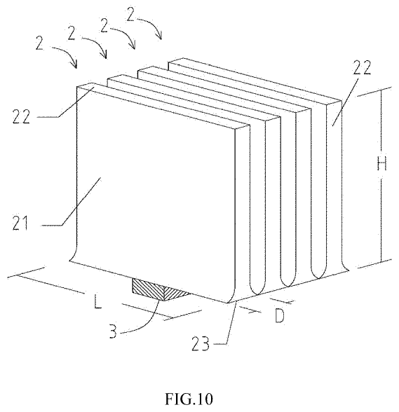

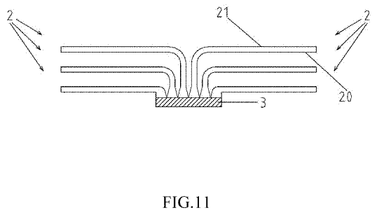

As demonstrated in FIGS. 5 to 9, and 11, the plate vapor chamber may have a variety of overall shapes, such as, for example, the shape of a wedge as shown in FIG. 8 and the shapes with bent plates 20 and 21 as shown in FIGS. 6 and 7. In addition, as demonstrated in FIG. 9, the plate vapor chamber may have a portion of a periphery of two plates(20 and 21) being taken in contact with the heat source 3 to serve as the evaporation area. Further, as demonstrated in FIG. 11, the plate vapor chamber may be bent to project laterally in response to a height limitation. FIG. 10 shows a seventh embodiment of the present disclosure. As illustrated, in this embodiment, a plurality of the plate vapor chambers of FIG. 3 are arranged in an array and disposed on a heat source, totally covering the top surface of the heat source. Such array arrangement expands the two-dimensional phase-change heat transfer into a three-dimensional space and hence can achieve a higher heat flux density.

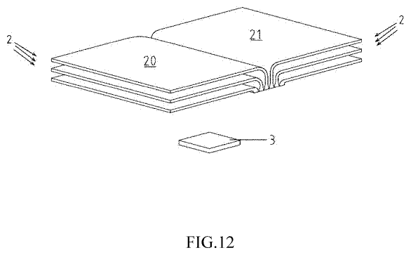

FIGS. 11 and 12 show an eighth embodiment of the present disclosure. As illustrated, in this embodiment, a plurality of the J-shaped plate vapor chambers of FIG. 7 are arranged in an array and disposed on a heat source, totally covering the top surface of the heat source. Differing from the seventh embodiment, each plate vapor chamber of the array of this embodiment is bent to project laterally from the heat source and is thus particularly suitable for applications where there exists a height limitation.

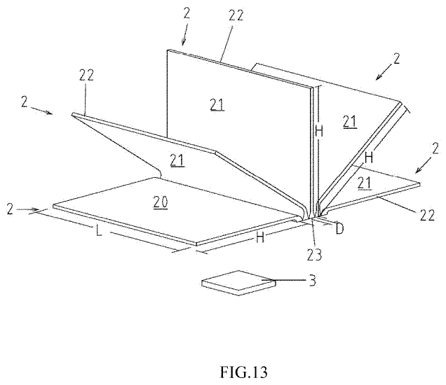

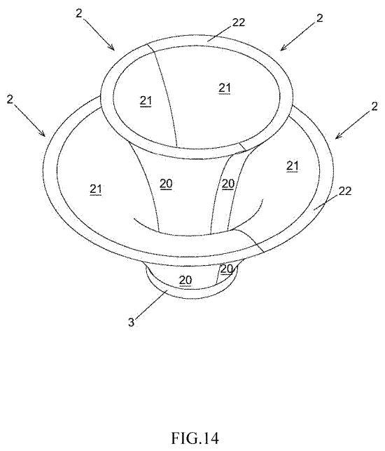

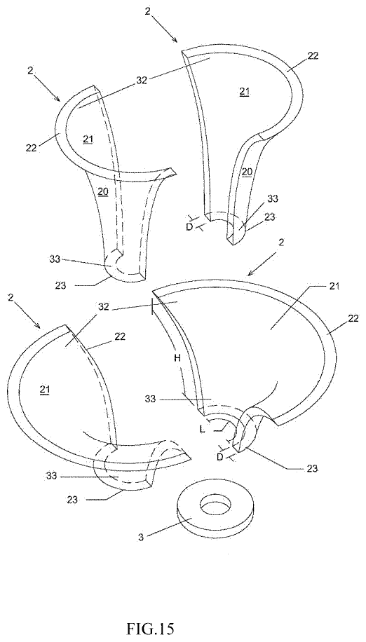

FIG. 13 shows a three-dimensional view of a plate vapor chamber array in accordance with a ninth embodiment of the present disclosure. FIG. 14 shows a three-dimensional view of a plate vapor chamber assembled array in accordance with a tenth embodiment of the present disclosure. FIG. 15 is an exploded perspective view of FIG. 14.

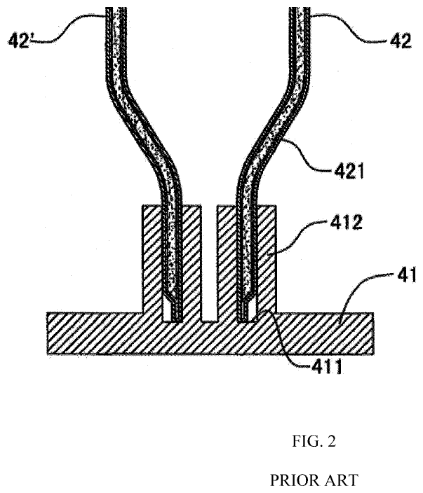

In FIGS. 14 and 15, 2 is plate vapor chamber. 3 is a heat source. L is the length of the first outside surface portion of the frame. H is the height of the chamber. D is the thickness of the chamber. 20 is the first plate and 21 is the second plate. The first end 33 of the chamber is the end of the chamber where the first outer surface portion of the frame is located, the second end 32 of the chamber is the other end of the chamber where the second outer surface portion of the frame is located. The height and the length thereof are the height and the length of this chamber before it is not bent; and the thickness of this chamber is the width of the first outside surface portion of the frame.

In FIGS. 14 and 15, it is shown four plate vapor chambers which are curved in the direction of the length and height. They can be used on and are not only used on a heat source of a circle-shape or an annulus-shape planar surface. In some other illustrative embodiments, one or a few plate vapor chambers can be disposed at the same time. If it is technically necessary, the curved annulus-shape plate vapor chamber can be spliced together by several parts. In FIGS. 14 and 15, it is shown two annulus-shape ones are be spliced together by four chambers.

In some other illustrative embodiments, single part or several parts of annulus shape can be disposed. In some other illustrative embodiments, the chamber thereof can be bent or not. The plate vapor chamber shown in FIGS. 14 and 15 has the same first portion of the narrow and elongated frame, a large-area vapor passage and a large-area plates of condensation zone; and it is accordance with the designing rule of the plate vapor chamber.

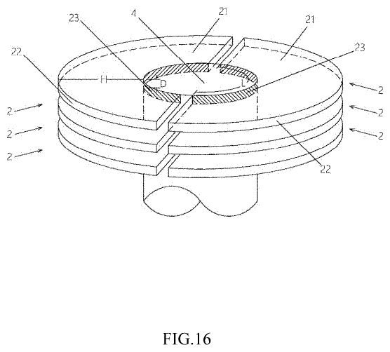

FIG. 16 shows a three-dimensional view of a plate vapor chamber assembled array in accordance with a eleventh embodiment of the present disclosure. In FIG. 16, it indicates plate vapor chambers of an annulus shape or a part of annulus shape. They can be used and are not only used on a heat source of a cylinder-shape or other curved surface.

In FIG. 16, 4 is a heat source of cylinder shape. 2 is plate vapor chambers. 20 and 21 are plates of the plate vapor chamber. 23 is the first outside surface portion of the frame, i.e. the inner arc length of the chamber. 22 is the second outside surface portion of the frame. H is the width of the annulus, i.e. the height of the chamber. L is the length of the first outside surface portion of the frame. D is the width of the first outside surface portion of the frame. In FIG. 16, the plate vapor chamber shown can be assembled and arrayed on a heat source in the manner a single or a plurality of plate vapor chambers and it is configured as a part of the body of the heat-generating device, i.e. the first portion of the plate vapor chamber's frame is the part of the body of the heat-generating device.

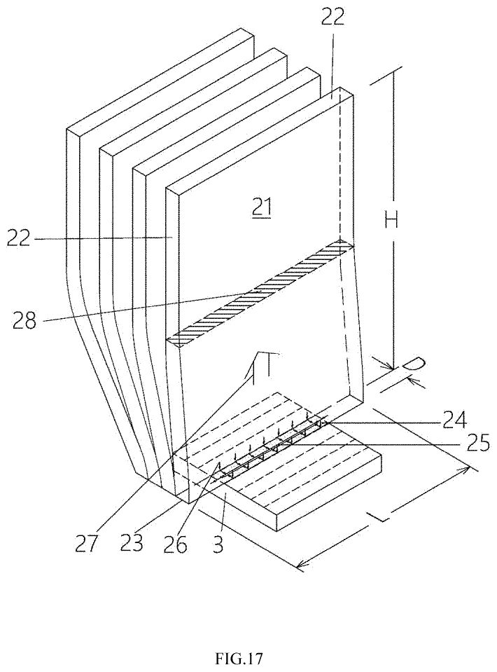

FIG. 17 shows working-principle view. In FIG. 17, 3 is a heat source. 20 and 21 are plates of a chamber. 22 is the second outside surface portion of the frame. 23 is the first outside surface portion of the frame. 24 is the evaporation zone. 25 is the center of the evaporation zone. 26 is the direction of the liquid to the evaporation zone. 27 is the direction of vapor diffusion. 28 is the section of vapor passage. L is the length of the first outside surface portion of the frame. H is the chamber's height. D is the thickness of the chamber and is also the width of the first outside surface portion of the frame.

Seen from the figures, compared with the conventional, the plate vapor chamber uses the narrow and flat frame as the evaporation zone and uses very large plates as the condensation zone so that there is huge increase in the width of the transportation of the liquid, tremendous increase in the ratio that the cross section of vapor passages to the area of evaporation zone, huge decrease in the distance from the edge to the center of the evaporation zone and significant increase in the ratio of the area of the condensation zone to the evaporation zone. Thus, this increases the heat transfer efficiency by an order of magnitude.

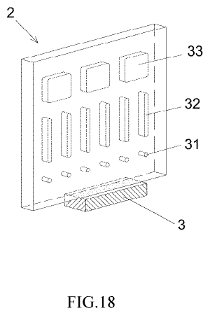

FIG. 18 shows the structural view of inner supporting of the plate vapor chamber. Wherein, 2 is plate vapor chamber. 3 is heat source. 31 is the dot-shape supporting. 32 is the line-shape supporting. 33 is the piece-shape supporting.

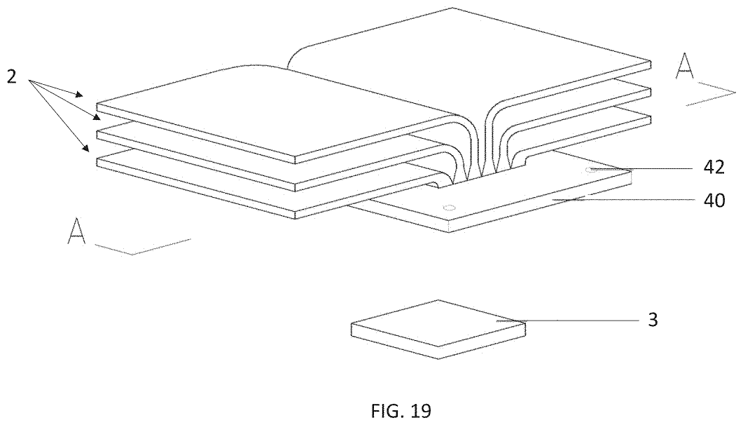

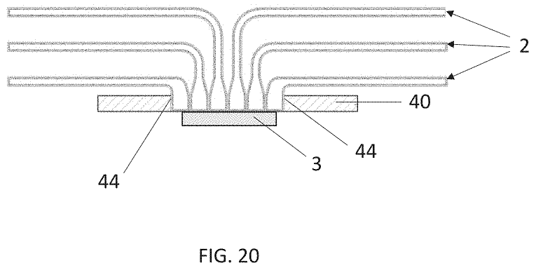

FIG. 19 shows a three-dimensional view and FIG. 20 shows a cross-sectional view of the clamp of a plate vapor chamber array like that illustrated in FIGS. 11-12 and includes a plate vapor chamber clamp 42 positioned in direct contact with the heat source 3 without any intervening structure. The plate vapor clamp may be coupled to a structure adjacent to the heat source 3 by bolts 42, or other attachment structure. The plate vapor chamber clamp 42 includes a metal plate that mechanically engages an edge 44 plate vapor chamber 2 array. Adjacent plate vapor chambers 2 are each directly in contact with each other. Direct contact between plate vapor chambers 2 and with the heat source 3 increase heat dissipation efficiency.

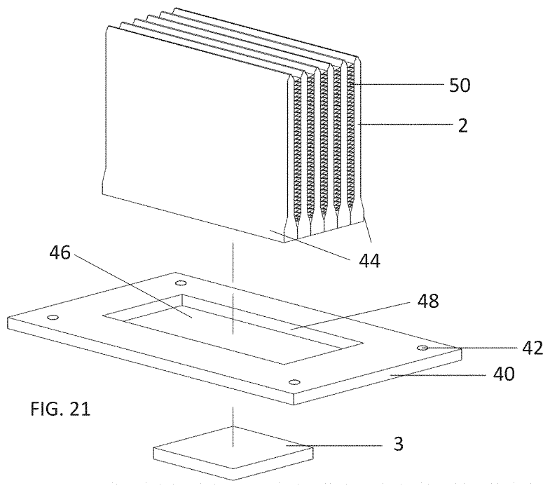

FIG. 21 shows an exploded three-dimensional view of a plate vapor chamber 2 with a clamp 40 but further including a heat dissipation fin 50. The clamp 40, like that of FIG. 20, includes at least one plate vapor chamber opening 46 within the clamp 40, a side-wall 48 of which engages an edge 44 of the vapor chamber 2 array. The heat dissipation fin 50 is coupled to inside edges of the plate vapor chamber 2 array to join adjacent plate vapor chambers 2 of the array to each other at select locations along a length of the plate vapor chambers 2. The heat dissipation fin 50 is formed of a thermally conductive material, such as copper, aluminum, zinc, graphite or other thermally conductive materials used in heat transfer. In the specific, non-limiting, example illustrated in FIGS. 21-23, the heat dissipation fin 50 follows a zig-zag pattern between adjacent vapor plate chambers 2 so that the heat dissipation fin 50 has a pleated shape. The heat dissipation fin 50 may be attached to the vapor plate chambers 2 using methods standard in the industry for coupling heat conductive materials such as by thermally conductive adhesive, solder, welding and even in some embodiments through pressure-fit or mechanical engagement.

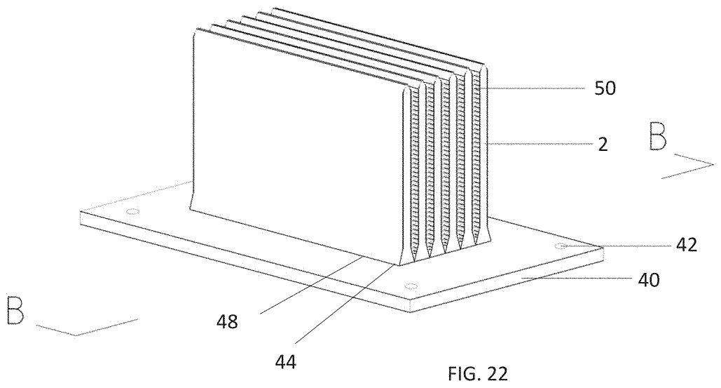

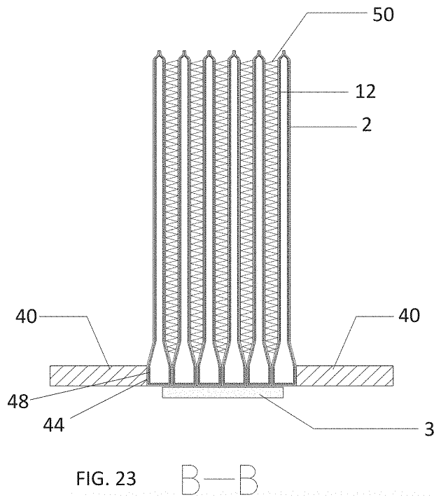

FIG. 22 shows an assembled three-dimensional view of the plate vapor chamber 2 array assembly of FIG. 21. When assembled, the sidewall 48 of the clamp engages the edge 44 of the plate vapor chamber 2 array. FIG. 23 shows a cross-sectional view of the assembled plate vapor chamber 2 array assembly of FIG. 22 taken along section line B-B.

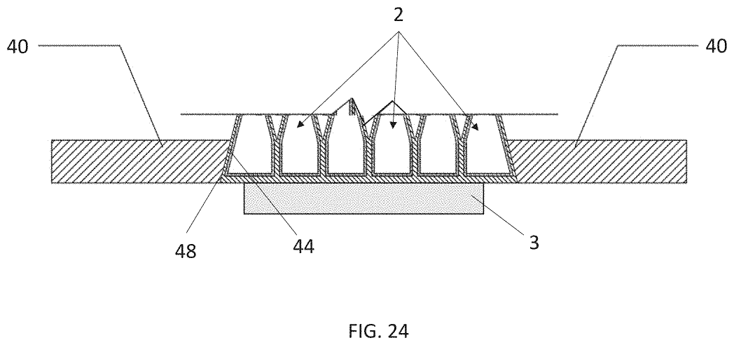

FIG. 24 shows a cross-sectional view of an assembled plate vapor chamber 2 array assembly similar to that in FIG. 20 or FIG. 22, emphasizing a first clamp embodiment, with the lengths of the plate vapor chambers 2 not showing to emphasize a first clamp embodiment. As illustrated in the close-up view shown in FIG. 24, the adjacent plate vapor chambers 2 are each in direct contact each other adjacent plate vapor chambers 2, and in direct contact with the heat source 3. In other embodiments, a gap may be included between adjacent plate vapor chambers 2. By non-limiting examples, with a central processing unit (CPU) or graphics processing unit (GPU), because the heat source area is concentrated and the heat generated is large, the plate vapor chambers are more efficient if they are in ditect contact with each other and require a relatively large size. For similar cylinders, the heat flux density is relatively low, and the plate vapor chambers may have gaps between them and the plate vapor chamber size may be smaller. For a specific CPU/GPU embodiment, adjacent plate vapor chambers should be spaced in close arrangement with a spacing less than or equal to 4 millimeters (mm), in some embodiments less than or equal to 3 mm, in some embodiments less than or equal to 2 mm, in some embodiments less than or equal to 1 mm, and in some embodiments in direct contact. For larger heat-generating components with low heat flux density, the spacing between adjacent plate vapor chambers can be as large as 10 mm.

The clamp 40 is mounted to the heat source or to a surface near the heat source to press the plate vapor chamber 2 assembly tightly against the heat source 3. The inner surface 48 of the at least one plate vapor chamber opening 46 is angled to mechanically engage the angled outer edge 44 of the plate vapor chambers 2. The inner surface 48 is angled non-perpendicular to an upper and lower surface of the clamp 40.

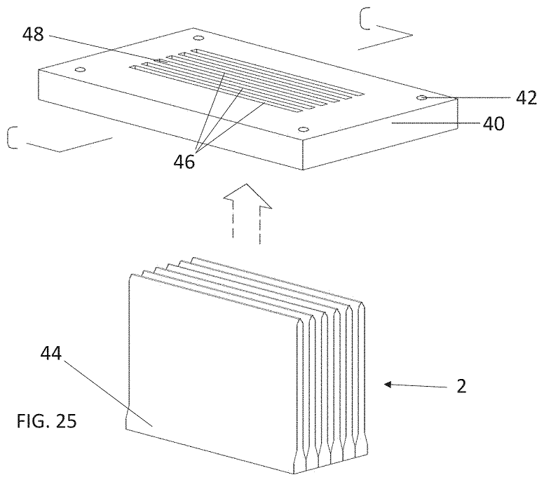

FIG. 25 shows an exploded three-dimensional view of a plate vapor chamber 2 array assembly with a second clamp 40 embodiment emphasizing assembly of a straight plate vapor chamber 2 assembly with the second clamp 40 embodiment. The second clamp 40 embodiment, like the first clamp 40 embodiment, includes at least one plate vapor chamber opening 46. In the second clamp 40 embodiment, however, there are a plurality of plate vapor chamber openings 46 corresponding to the number of plate vapor chambers 2 in the plate vapor chamber 2 array that mates with the clamp 40. In other embodiments, multiple plate vapor chambers 2 may be inserted into a single, larger-sized plate vapor chamber openings 46 so that the number of plate vapor chamber openings 46 does not match the number of plate vapor chambers 2.

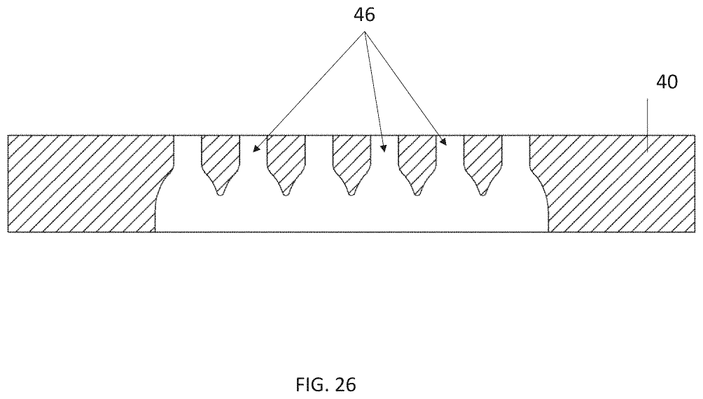

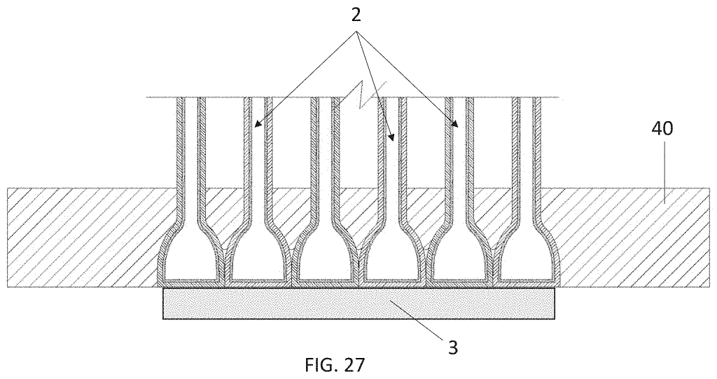

FIG. 26 shows a cross-sectional view of a clamp 40 according to the second embodiment with plate vapor chamber voids 52 taken along section lines C-C of FIG. 25. The plate vapor chambers 2 of FIG. 25 and the heat source 3 are removed for clarity. The plate vapor chamber openings 46 in this embodiment may be shaped to match the outer shape of the plate vapor chambers 2 to which it will mate when the plate vapor chambers 2 are inserted into the at least one plate vapor chamber opening 46. In other embodiments, the shapes of the at least one plate vapor chamber opening 46 may be shaped merely sufficient to maintain mechanical pressure against the plate vapor chamber 2 array to retain it in place against the heat source 3 (FIG. 27). FIG. 27 shows a cross-sectional view of the clamp 40 of FIG. 26 with a portion of a cross-sectional view of a plate vapor chamber 2 array assembled with the clamp 40 and pressing the lower surface of the plate vapor chamber 2 array directly against the heat source 3. The sides of adjacent plate vapor chambers 2 may also be in direct contact with each other adjacent plate vapor chamber 2, or spaced as described previously.

### INDUSTRIAL APPLICABILITY

The application of the present disclosure in industries can not only greatly reduce the dimension and height of heat dissipation apparatuses but also highly improve the heat flux density of heat dissipation apparatuses.

Heat dissipation apparatuses incorporating the plate vapor chamber(s) can be used for the heat dissipation of high-power semiconductor devices like high-power transistors, high-power semiconductor laser devices, high-power light emitting diodes (LEDs), high-power central processing units (CPUs), high-power graphics processing units (GPUs) and so on.

In occasions where heat dissipation apparatuses incorporating the plate vapor chamber(s) is used, all water cooling methods can be replaced by air cooling methods, and active cooling methods can be replaced by passive cooling methods.

Heat dissipation apparatuses incorporating the plate vapor chamber(s) can enable the reduction of height of a tower case of a desktop computer to nearly a thickness of a laptop computer.

It will be understood that implementations of a plate vapor chamber are not limited to the specific assemblies, devices and components disclosed in this document, as virtually any assemblies, devices and components consistent with the intended operation of a plate vapor chamber. Accordingly, for example, although particular plate vapor chambers, and other assemblies, devices and components are disclosed, such may include any shape, size, style, type, model, version, class, measurement, concentration, material, weight, quantity, and/or the like consistent with the intended operation of a plate vapor chamber. Implementations are not limited to uses of any specific assemblies, devices and components; provided that the assemblies, devices and components selected are consistent with the intended operation of plate vapor chambers.

Accordingly, the components defining any plate vapor chamber implementations may be formed of any of many different types of materials or combinations thereof that can readily be formed into shaped objects provided that the components selected are consistent with the intended operation of a plate vapor chamber implementation. In instances where a part, component, feature, or element is governed by a standard, rule, code, or other requirement, the part may be made in accordance with, and to comply under such standard, rule, code, or other requirement.

Various plate vapor chambers may be manufactured using conventional procedures as added to and improved upon through the procedures described here. Some components defining plate vapor chambers may be manufactured simultaneously and integrally joined with one another, while other components may be purchased pre-manufactured or manufactured separately and then assembled with the integral components. Various implementations may be manufactured using conventional procedures as added to and improved upon through the procedures described here.

Accordingly, manufacture of these components separately or simultaneously may involve extrusion, pultrusion, vacuum forming, injection molding, blow molding, casting, forging, cold rolling, milling, drilling, reaming, turning, grinding, stamping, cutting, bending, welding, soldering, hardening, riveting, punching, plating, and/or the like. If any of the components are manufactured separately, they may then be coupled with one another in any manner, such as with adhesive, a weld, a fastener (e.g. a bolt, a nut, a screw, a nail, a rivet, a pin, and/or the like), wiring, any combination thereof, and/or the like for example, depending on, among other considerations, the particular material forming the components.

It will be understood that any methods of forming or using plate vapor chambers are not limited to the specific order of steps as disclosed in this document. Any steps or sequence of steps of the assembly of plate vapor chambers indicated herein are given as examples of possible steps or sequence of steps and not as limitations, since various assembly processes and sequences of steps may be used to assemble plate vapor chambers.

The implementations of the plate vapor chambers described are by way of example or explanation and not by way of limitation. Rather, any description relating to the foregoing is for the exemplary purposes of this disclosure, and implementations may also be used with similar results for a variety of other applications requiring a plate vapor chamber.

What is claimed is:

1. A plate vapor chamber array assembly comprising:
a plurality of plate-shaped chambers joined in an array with each of the vapor plate chambers in close arrangement with at least one adjacent plate vapor chamber of the array, each plate-shaped chamber formed by a first plate spaced from a second plate forming a condensation area having a length and a height, the first plate and the second plate connected together by a frame, the frame forming an evaporation area on a first end of the chamber between a first end of the first plate and a first end of the second plate, the evaporation area having a thickness defined as a distance between the first plate and the second plate, and an evaporation length defined as a length of the evaporation area, the evaporation length of the evaporation area within the chamber being greater than the thickness of the evaporation area, the frame sealing the first plate to the second plate thereby forming a sealed chamber having an enclosed and hollow space defined by the chamber on an inside of the first plate, the second plate, and the frame;
a capillary structure layer within each of the plurality of plate-shaped chambers, each chamber and adjacent inner surfaces of at least a part of the first plate and the second plate, the capillary structure layer for each of the plurality of plate-shaped chambers further attached to an inner surface of at least a part of the frame;
a phase transition working medium sealed within the sealed chamber of each of the plurality of plate-shaped chambers, each of the sealed chambers being evacuated; and
a vapor chamber clamp surrounding the array and comprising at least one vapor chamber opening within the vapor chamber clamp and having an inner surface of the vapor chamber clamp opening configured to engage an outer edge of at least two of the plate vapor chambers of the array, wherein the vapor chamber clamp is configured to press a surface of the plate vapor chamber array directly against the heat source;
wherein the evaporation area is configured to be coupled with the evaporation length and its thickness in direct, planar, physical contact with a heat source; and
wherein the condensation area is configured to not be in direct physical contact with the heat source, and is configured to extend away from the heat source.

2. The plate vapor chamber array assembly of claim 1, wherein the evaporation length of the evaporation area within the chamber is greater than the thickness of the evaporation area by at least five times.

3. The plate vapor chamber array assembly of claim 1, wherein the evaporation length of the evaporation area within the chamber is greater than the thickness of the evaporation area by at least two times.

4. The plate vapor chamber array assembly of claim 1, wherein the at least one vapor chamber opening in the clamp comprises a plurality of vapor chamber openings, each sized to receive at least one plate vapor chamber therethrough.

5. The plate vapor chamber array assembly of claim 1, wherein the inner surface of the at least one vapor chamber clamp opening is angled non-perpendicular to an upper and lower surface of the vapor chamber clamp.

6. The plate vapor chamber array assembly of claim 4, wherein the inner surface of each of the at least one vapor chamber clamp openings is shaped to mate with the plurality of plate shaped chambers.

7. The plate vapor chamber array assembly of claim 1, further comprising at least one heat dissipating fin extending between at least two chambers of the plurality of plate-shaped chambers.

8. The plate vapor chamber array assembly of claim 7, wherein the at least one heat dissipating fin is in a zig-zag shape extending back and forth between the at least two chambers of the plurality of plate-shaped chambers.

9. A plate vapor chamber array assembly comprising:
a plurality of plate vapor chambers joined in an array with each of the vapor plate chambers in close arrangement with at least one adjacent plate vapor chamber of the array, each plate vapor chamber formed by a first plate spaced from a second plate forming a condensation area having a length and a height, the first plate and the second plate connected together by a frame, the frame forming an evaporation area on a first end of the chamber between a first end of the first plate and a first end of the second plate, the evaporation area having a thickness defined as a distance between the first plate and the second plate, and an evaporation length defined as a length of the evaporation area, the evaporation length of the evaporation area within the chamber being greater than the thickness of the evaporation area, the frame sealing the first plate to the second plate thereby forming a sealed chamber having an enclosed and hollow space defined by the chamber on an inside of the first plate, the second plate, and the frame, the sealed chamber being evacuated; and
a vapor chamber clamp surrounding the array and having an inner surface of a vapor chamber clamp opening configured to engage an outer edge of at least two of the plate vapor chambers of the array and to press a surface of the plate vapor chamber array directly against the heat source;
wherein the evaporation area is configured to be coupled with the evaporation length and its thickness in direct, planar, physical contact with a heat source; and
wherein the condensation area is configured to not be in direct physical contact with the heat source, and is configured to extend away from the heat source.

10. The plate vapor chamber array assembly of claim 9, wherein the evaporation length of the evaporation area within the chamber is greater than the thickness of the evaporation area by at least five times.

11. The plate vapor chamber array assembly of claim 9, wherein the at least one vapor chamber opening in the clamp comprises a plurality of vapor chamber openings, each sized to receive at least one plate vapor chamber therethrough.

12. The plate vapor chamber array assembly of claim 9, wherein the inner surface of the at least one vapor chamber clamp opening is angled non-perpendicular to an upper and lower surface of the vapor chamber clamp.

13. The plate vapor chamber array assembly of claim 12, wherein the inner surface of each of the at least one vapor chamber clamp openings is shaped to mate with the plurality of plate shaped chambers.

14. The plate vapor chamber array assembly of claim 9, further comprising at least one heat dissipating fin extending between at least two chambers of the plurality of plate-shaped chambers.

15. A plate vapor chamber array assembly comprising:
a plurality of plate vapor chambers joined in an array, each plate vapor chamber comprising a condensation area having a length and a height, the first plate and the second plate connected together by a frame, the frame forming an evaporation area on a first end of the chamber and sealing the first plate to the second plate thereby forming a sealed chamber having an enclosed and hollow space defined by the chamber on an inside of the first plate, the second plate, and the frame, the sealed chamber being evacuated; and
a vapor chamber clamp surrounding the array and having an inner surface of a vapor chamber clamp opening configured to engage an outer edge of at least two of the plate vapor chambers of the array and to press a surface of the plate vapor chamber array directly against the heat source.

16. The plate vapor chamber array assembly of claim 15, wherein the at least one vapor chamber opening in the clamp comprises a plurality of vapor chamber openings, each sized to receive at least one plate vapor chamber therethrough.

17. The plate vapor chamber array assembly of claim 15, wherein the inner surface of the at least one vapor chamber clamp opening is angled non-perpendicular to an upper and lower surface of the vapor chamber clamp.

18. The plate vapor chamber array assembly of claim 15, wherein at least two of the vapor plate chambers in direct contact with at least one adjacent plate vapor chamber of the array.

19. The plate vapor chamber array assembly of claim 15, further comprising at least one heat dissipating fin extending between at least two chambers of the plurality of plate-shaped chambers.

20. The plate vapor chamber array assembly of claim 19, wherein the at least one heat dissipating fin is in a zig-zag shape extending back and forth between the at least two chambers of the plurality of plate-shaped chambers.
